(19) United States
(12) Patent Application Publication
(10) Pub. No.: US 2025/0380395 A1
(43) Pub. Date: Dec. 11, 2025

(54) MEMORY CELL COMPRISING p-TYPE TELLURIUM OXIDE SEMICONDUCTOR LAYER AND METHOD FOR MANUFACTURING SAME

(71) Applicant: POSTECH RESEARCH AND BUSINESS DEVELOPMENT FOUNDATION, Pohang-si (KR)

(72) Inventor: Yong-Young NOH, Pohang-si (KR)

(21) Appl. No.: 19/217,415

(22) Filed: May 23, 2025

(30) Foreign Application Priority Data
May 24, 2024 (KR) 10-2024-0067998
May 19, 2025 (KR) 10-2025-0064622

(51) Int. Cl. H10B 12/00

(52) U.S. Cl. CPC H10B 12/00

(57) ABSTRACT

Disclosed is a memory cell comprising an amorphous p-type tellurium oxide semiconductor layer and method for manufacturing same. The memory cell of the present disclosure comprises a write n-type transistor comprising a first semiconductor layer and a read p-type transistor comprising a second semiconductor layer, wherein the first semiconductor layer comprises an n-type semiconductor, the second semiconductor layer 300b comprises an amorphous p-type semiconductor, and it shows the characteristics of a non-volatile memory cell, and the write n-type transistor and the read p-type transistor can be alternately vertically stacked in multiple layers of two, three or more.

### CROSS REFERENCE TO RELATED APPLICATION

The present application claims the benefit of priority to Korean Patent Application No. 10-2024-0067998 filed on May 24, 2024, and Korean Patent Application No. 10-2025-0064622 filed on May 19, 2025, in the Korean Intellectual Property Office. The aforementioned applications are hereby incorporated by reference in their entireties.

### TECHNICAL FIELD

The present disclosure relates to a memory cell comprising p-type tellurium oxide semiconductor layer and method for manufacturing same.

### BACKGROUND ART

For the past several decades, SRAM and DRAM-based memories have been widely used in the non-volatile memory field. SRAM has a very fast memory write-read speed, but its structure is composed of multiple transistors, so its structure has limitations in applying it to recent high-density structures. On the other hand, DRAM (Dynamic Random Access Memory) has a simple structure and is easy to integrate, so it is used as a large-capacity temporary memory device. The DRAM structure is composed of cells in a 1T-1C structure, so its structure is relatively simple and advantageous for high integration. However, DRAM does not have a fast write-read speed, so improvement in memory operation speed is required for application to in-memory computing, etc.

Recently, various memory structures have been proposed to improve the operation speed of DRAM, and the Capacitance less (capless) DRAM structure is being studied. 2T0C DRAM, which is a 2T gain cell memory, is considered a promising candidate that uses oxide semiconductor (OS) as a channel material. The memory cell consists of a transistor for writing information and a transistor for reading information. Capless DRAMs have a problem of discharging the read bitline when using nMOSFETs as write and read transistors.

### DISCLOSURE

### Technical Problem

The purpose of the present disclosure is to solve the above problems, and to provide a memory cell comprising p-type tellurium oxide semiconductor layer.

In addition, another purpose of the present disclosure is to provide a method for manufacturing a memory cell comprising p-type tellurium oxide semiconductor layer.

### Technical Solution

One aspect of the present disclosure provides a non-volatile memory cell 1 comprising a write n-type transistor 10a comprising a first semiconductor layer 300a and a read p-type transistor 10b comprising a second semiconductor layer 300b, wherein the first semiconductor layer 300a comprises an n-type semiconductor, and the second semiconductor layer 300b comprises an amorphous p-type semiconductor.

In addition, the non-volatile memory cell 1 may be a capless non-volatile memory cell that does not comprise a capacitor.

In addition, the amorphous p-type semiconductor may comprise a chalcogen atom comprising at least one selected from the group consisting of a selenium atom (Se) and a sulfur atom (S); and a tellurium composite comprising a tellurium (Te) atom and a tellurium oxide.

In addition, the chalcogen atom may be alloyed with the tellurium composite.

In addition, the amorphous p-type semiconductor may be represented by Chemical Formula 1 below.

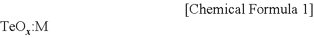

in Chemical Formula 1, M is a sulfur atom (S) or a selenium atom (Se), and x is in a range of 0<x<2.

In addition, the tellurium atom of the amorphous p-type semiconductor may comprise an ionization state of Te⁴⁺, an ionization state of Te²⁺ and a non-ionization state of Te⁰.

In addition, the tellurium oxide may comprise a tellurium monoxide (TeO) and a tellurium dioxide (TeO₂).

In addition, the amorphous p-type semiconductor may be in an oxygen-deficient state.

In addition, the non-volatile memory cell 1 may be a vertically stacked structure of the write n-type transistor 10a and the read p-type transistor 10b.

In addition, the write n-type transistor 10a and the read p-type transistor 10b may be stacked in a vertical direction in multiple repetitions, may be stacked in a repeating manner 2 or more times, and may be stacked in a repeating manner 2 to 100,000 times.

In addition, the write n-type transistor 10a may comprise a first gate electrode 100a, a first insulating layer 200a positioned on the first gate electrode 100a, a first semiconductor layer 300a positioned on the first insulating layer 200a, a first source electrode 400a and a first drain electrode 500a, and the read p-type transistor 10b may comprise a second gate electrode 100b, a second insulating layer 200b positioned on the second gate electrode 100b, a second semiconductor layer 300b positioned on the second insulating layer 200b, a second source electrode 400b and a second drain electrode 500b, and an insulating intermediate layer 700 may be positioned between the write n-type transistor 10b and the read p-type transistor 10b.

In addition, the insulating intermediate layer 700 may comprise: a first insulating intermediate layer 710 comprising at least one selected from the group consisting of SU-8, CYTOP, benzocyclobutene (BCB) and polyimide; and a second insulating intermediate layer 720 positioned on the first insulating intermediate layer and comprising at least one selected from the group consisting of Al₂O₃, HfO₂, a laminate of Al₂O₃ and HfO₂ (Al₂O₃/HfO₂), CYTOP, BCB and polyimide, wherein the first insulating intermediate layer 710 may be positioned on the second insulating intermediate layer 720.

In addition, the non-volatile memory cell 1 may further comprise a via 800 electrically connecting the first drain electrode 500a of the write n-type transistor 10a and the second gate electrode 100b of the read p-type transistor 10b.

In addition, the n-type semiconductor may be an n-type chalcogenide semiconductor or an n-type oxide semiconductor, and may comprise at least one selected from the group consisting of MOS₂, ZnO, In₂O₃, TiO₂, Ga₂O₃, VO₂, V₄O₉, VOₓ, indium tin oxide (ITO), indium zinc oxide (IZO), indium zinc tin oxide (IZTO), indium gallium zinc oxide (IGZO), indium tungsten oxide (IWO) and zinc tin oxide (ZTO).

In addition, the first gate electrode 100a and the second gate electrode 100b may each independently comprise at least one selected from the group consisting of n-doped silicon (n-doped Si), p-doped silicon (p-doped Si), gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotubes (CNT), silver nanowires (Ag NW), indium tin oxide and poly(3,4-ethylenedioxythiophene) polystyrene sulfonate (PEDOT:PSS).

In addition, the first source electrode 400a and the second source electrode 400b may each independently comprise at least one selected from the group consisting of gold (Au), silver (Ag), platinum (Pt), titanium (Ti), aluminum (Al), tungsten (W), magnesium (Mg), calcium (Ca), ytterbium (Yb), chromium (Cr), nickel (Ni), gold oxide, platinum oxide, silver oxide, palladium oxide, iron oxide, graphene, carbon nanotubes (CNT), silver nanowires (Ag nanowires (Ag NW), indium tin oxide and poly(3,4-ethylenedioxythiophene) polystyrene sulfonate (PEDOT:PSS).

In addition, the first drain electrode 500a and the second drain electrode 500b may each independently comprise at least one selected from the group consisting of gold (Au), silver (Ag), platinum (Pt), titanium (Ti), aluminum (Al), tungsten (W), magnesium (Mg), calcium (Ca), ytterbium (Yb), chromium (Cr), nickel (Ni), gold oxide, platinum oxide, silver oxide, palladium oxide, iron oxide, graphene, carbon nanotubes (CNT), silver nanowires (Ag NW), indium tin oxide and poly(3, 4-ethylenedioxythiophene) polystyrene sulfonate (PEDOT:PSS).

In addition, the substrate 600 may comprise at least one selected from the group consisting of glass, silicon, p-silicon, n-silicon, fluorine-doped tin oxide (FTO), indium tin oxide (ITO), indium zinc oxide (IZO), indium zinc tin oxide (IZTO), aluminum zinc oxide (AZO), indium tin oxide-silver-indium tin oxide (ITO-Ag-ITO), indium zinc oxide-silver-indium zinc oxide (IZO-Ag-IZO), indium zinc tin oxide-silver-indium zinc oxide (IZTO-Ag-IZTO), aluminum zinc oxide-silver-aluminum zinc oxide

(AZO-Ag-AZO), nickel, stainless steel, zinc-coated carbon steel, pure carbon steel, copper, titanium, zinc, steel, polyester, polyethylene terephthalate (PET), polybutylene terephthalate (PBT), polyethylene naphthalate (PEN), polystyrene (PS), polymethyl methacrylate (PMMA), polyimide (PI), polyamide, polyethylene, polypropylene, polyurea, polyurethane poly(p-xylylene), parylene, polydimethylsiloxane (PDMS), Cytop and polyvinyl pyrrolidone (PVP).

In addition, the non-volatile memory cell 1 may further comprise: a write word line (WWL) connected to a first gate electrode 100a of the write n-type transistor 10a; a write bit line (WBL) connected to a first source electrode 400a of the write n-type transistor 10a; a read bit line (RBL) connected to a second source electrode 400b of the read p-type transistor 10b; and a read word line (RWL) connected to a second drain electrode 500b of the read p-type transistor 10b; wherein the first drain electrode 500a of the write n-type transistor 10a may be connected to the second gate electrode 100b of the read p-type transistor 10b.

Another aspect of the present disclosure provides a method for manufacturing a non-volatile memory cell 1, the method comprising: (a) manufacturing one selected from the group consisting of a write n-type transistor 10a comprising a first semiconductor layer 300a and a read p-type transistor 10b comprising a second semiconductor layer 300b; and (b) stacking vertically the other selected from the group consisting of the write n-type transistor 10a comprising the first semiconductor layer 300a and the read p-type transistor 10b comprising the second semiconductor layer 300b on the one transistor manufactured in step (a); wherein the first semiconductor layer 300a comprises an n-type semiconductor and the second semiconductor layer 300b comprises an amorphous p-type semiconductor.

In addition, the method for manufacturing a non-volatile memory cell 1 may further comprise, between step (a) and step (b), (a′) forming an insulating intermediate layer 700 on the transistor manufactured in step (a).

In addition, the temperature of the substrate of the non-volatile memory cell may be in a range of 5 to 50° C. in step (a) and step (b).

In addition, the first semiconductor layer 300a may be annealed at a temperature in a range of 150 to 400° C. in step (a) or step (b).

In addition, the second semiconductor layer 300b may be annealed at a temperature in a range of 150 to 400°° C. in step (a) or step (b).

### Advantageous Effect

The present disclosure can provide a memory cell comprising an amorphous p-type tellurium oxide semiconductor layer with a capacitance less DRAM structure.

In the non-volatile memory cell of the present disclosure, a write n-type transistor and a read p-type transistor can be vertically stacked by repeating multiple times.

In the method for manufacturing the non-volatile memory cell of the present disclosure, a read p-type transistor comprising a p-type tellurium oxide semiconductor layer capable of a low-temperature process is used, so that a write n-type transistor and a read p-type transistor can be stacked in three or more layers.

The method for manufacturing of the present can The manufacturing method of the present disclosure performs continuous vertical or horizontal stacking at a low process temperature, so that the integration density of DRAM memory cells can be significantly increased and a power consumption can be reduced due to a very low transistor leakage current.

### BRIEF DESCRIPTION OF THE DRAWINGS

These drawings are for the purpose of describing exemplary embodiments of the present disclosure, and therefore the technical idea of the present disclosure should not be construed as being limited to the accompanying drawings:

FIG. 1 is a cross-sectional view of a non-volatile memory cell in which a read p-type transistor is vertically stacked on a write n-type transistor according to an embodiment of the present disclosure.

FIG. 2 is a circuit diagram of a non-volatile memory cell in which a write n-type transistor and a read p-type transistor are combined according to an embodiment of the present disclosure.

FIG. 3 is a flowchart showing a method for manufacturing a non-volatile memory cell according to an embodiment of the present disclosure.

FIG. 4 is a graph showing the XPS (X-ray photoelectron spectroscopy) selenium (Se) 3p spectrum of TeOₓ:Se alloyed with selenium (Se) according to Example 1 and a pristine TeOx sample not alloyed with selenium (Se) according to Comparative Example 1.

FIG. 5 is a graph showing the transfer characteristics of TeOₓ:Se and TeOₓ thin film transistors (TFTs) according to Example 1 and Comparative example 1 of the present disclosure.

FIG. 6 is a graph showing the output curve of the TeOₓ:Se thin film transistor (TFT) according to Example 1.

FIG. 7A is a graph showing the transfer curves of 80 TeOₓ:Se thin film transistor (TFT) devices manufactured on a 4-inch wafer under optimized conditions (VDS=−0.1 V) according to Example 1, and the inserted figure is an optical image of the thin film transistor (TFT) array on a 4-inch SiO₂ wafer.

FIG. 7B is a graph showing statistical results of field-effect hole mobility (μₙ) of the thin film transistor (TFT) according to Example 1 of the present disclosure.

FIG. 8 is a transfer curve of Examples 1 and 2 of the present disclosure.

FIG. 9 is a graph showing non-volatile results of a vertical non-volatile memory cell (CMOS of 2T0C DRAM) of Example 3 of the present disclosure.

FIG. 10 is a graph showing characteristic analysis of a vertical non-volatile memory cell (CMOS of 2T0C DRAM) of Example 3 of the present disclosure.

### DESCRIPTION OF THE PREFERRED EMBODIMENTS

Herein after, embodiments of the present disclosure will be described in detail with reference to the accompanying drawings in such a manner that the ordinarily skilled in the art can easily implement the embodiments of the present disclosure.

The description given below is not intended to limit the present disclosure to specific Examples. In relation to describing the present disclosure, when the detailed description of the relevant known technology is determined to unnecessarily obscure the gist of the present disclosure, the detailed description may be omitted.

The terminology used herein is for the purpose of describing particular examples only and is not intended to limit the scope of the present disclosure. As used herein, the singular forms “a”, “an”, and “the” are intended to comprise the plural forms as well unless the context clearly indicates otherwise. It will be further understood that the terms “comprise” or “have” when used in the present disclosure specify the presence of stated features, integers, steps, operations, elements and/or combinations thereof, but do not preclude the presence or addition of one or more other features, integers, steps, operations, elements, and/or combinations thereof.

Terms comprising ordinal numbers used in the specification, “first”, “second”, etc. can be used to discriminate one component from another component, but the order or priority of the components is not limited by the terms unless specifically stated. These terms are used only for the purpose of distinguishing a component from another component. For example, without departing from the scope of the present disclosure, a first component may be referred as a second component, and a second component may be also referred to as a first component.

In addition, when it is mentioned that a component is “formed” or “stacked” on another component, it should be understood such that one component may be directly attached to or directly stacked on the front surface or one surface of the other component, or an additional component may be disposed between them.

Hereinafter, a memory cell comprising p-type tellurium oxide semiconductor layer and method for manufacturing same will be described in detail. However, those are described as examples, and the present disclosure is not limited thereto and is only defined by the scope of the appended claims.

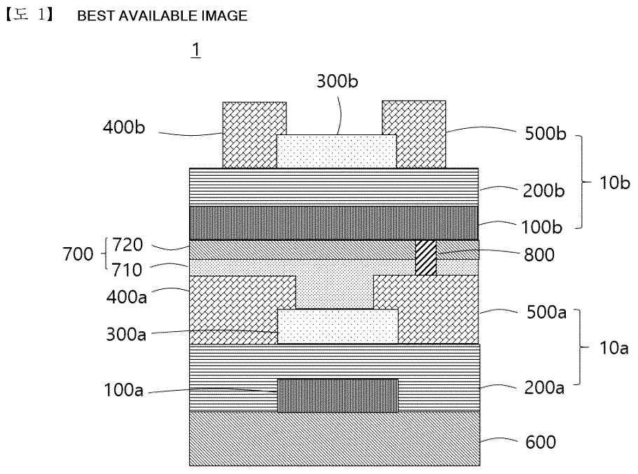

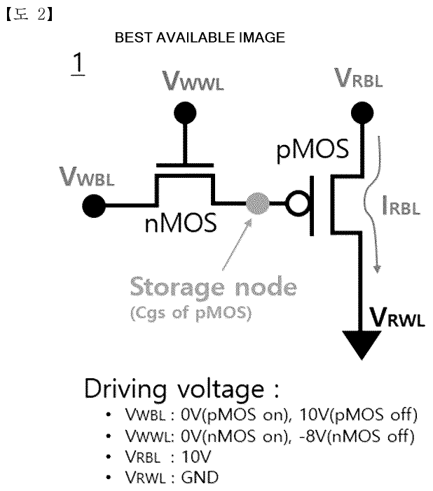

FIG. 1 is a cross-sectional view of a non-volatile memory cell in which a read p-type transistor 10b is vertically stacked on a write n-type transistor 10a according to an embodiment of the present disclosure and FIG. 2 is a circuit diagram of a non-volatile memory cell in which a write n-type transistor and a read p-type transistor 10b are combined according to an embodiment of the present disclosure. Referring to FIG. 1 and according to one aspect of the present disclosure, it provides a non-volatile memory cell 1 comprising a write n-type transistor 10a comprising a first semiconductor layer 300a and a read p-type transistor 10b comprising a second semiconductor layer 300b, wherein the first semiconductor layer 300a comprises an n-type semiconductor, and the second semiconductor layer 300b comprises an amorphous p-type semiconductor.

In addition, the non-volatile memory cell 1 may be a capless non-volatile memory cell that does not comprise a capacitor.

In addition, the amorphous p-type semiconductor may comprise a chalcogen atom comprising at least one selected from the group consisting of a selenium atom (Se) and a sulfur atom (S); and a tellurium composite comprising a tellurium (Te) atom and a tellurium oxide.

In addition, the chalcogen atom may be alloyed with the tellurium composite.

In addition, the amorphous p-type semiconductor may be represented by Chemical Formula 1 below.

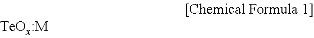

in Chemical Formula 1, M is a sulfur atom (S) or a selenium atom (Se) and x is in a range of 0<x<2.

In addition, the tellurium atom of the amorphous p-type semiconductor may comprise an ionization state of Te⁴⁺, an ionization state of Te²⁺ and a non-ionization state of Te⁰.

In addition, the tellurium oxide may comprise a tellurium monoxide (TeO) and a tellurium dioxide (TeO₂).

In addition, the amorphous p-type semiconductor may be in an oxygen-deficient state.

In addition, the non-volatile memory cell 1 may be the write n-type transistor 10a and the read p-type transistor 10b may be alternately vertically stacked.

In addition, the write n-type transistor 10a and the read p-type transistor 10b may be vertically and repeatedly stacked multiple times in the vertical direction, may be repeatedly stacked two or more times, and may be repeatedly stacked 2 to 100,000 times.

In addition, the write n-type transistor 10a may comprise a first gate electrode 100a, a first insulating layer 200a positioned on the first gate electrode 100a, a first semiconductor layer 300a positioned on the first insulating layer 200a, a first source electrode 400a and a first drain electrode 500a, and the read p-type transistor 10b may comprise a second gate electrode 100b, a second insulating layer 200b positioned on the second gate electrode 100b, a second semiconductor layer 300b positioned on the second insulating layer 200b, a second source electrode 400b and a second drain electrode 500b, and an insulating intermediate layer 700 may be positioned between the write n-type transistor 10b and the read p-type transistor 10b.

In addition, the insulating intermediate layer 700 may comprise a first insulating intermediate layer 710 comprising at least one selected from the group consisting of SU-8, CYTOP, benzocyclobutene (BCB) and polyimide; and a second insulating intermediate layer 720 positioned on the first insulating intermediate layer and comprising at least one selected from the group consisting of Al₂O₃, HfO₂, a laminate of Al₂O₃ and HfO₂ (Al₂O₃/HfO₂), CYTOP, BCB and polyimide, wherein the first insulating intermediate layer 710 may be positioned on the second insulating intermediate layer 720.

In addition, the non-volatile memory cell 1 may further comprise a via 800 electrically connecting the first drain electrode 500a of the write n-type transistor 10a and the second gate electrode 100b of the read p-type transistor 10b.

In addition, the n-type semiconductor may be an n-type chalcogenide semiconductor or an n-type oxide semiconductor, and may comprise at least one selected from the group consisting of MOS₂, ZnO, In₂O₃, TiO₂, Ga₂O₃, VO₂, V₄O₉, VOₓ, indium tin oxide (ITO), indium zinc oxide (IZO), indium zinc tin oxide (IZTO), indium gallium zinc oxide (IGZO), indium tungsten oxide (IWO) and zinc tin oxide (ZTO).

In addition, the first gate electrode 100a and the second gate electrode 100b each independently may comprise at least one selected from the group consisting of n-doped silicon (n-doped Si), p-doped silicon (p-doped Si), gold (Au), silver (Ag), platinum (Pt), titanium (Ti), aluminum (Al), tungsten (W), magnesium (Mg), calcium (Ca), ytterbium (Yb), chromium (Cr), nickel (Ni), molybdenum (Mo), gold oxide, platinum oxide, silver oxide, palladium oxide, iron oxide, graphene, carbon nanotubes (CNT), silver nanowires (Ag NW), indium tin oxide and poly(3,4-ethylenedioxythiophene) polystyrene sulfonate (PEDOT:PSS).

In addition, the first source electrode 400a and the second source electrode 400b each independently may comprise at least one selected from the group consisting of gold (Au), silver (Ag), platinum (Pt), titanium (Ti), aluminum (Al), tungsten (W), magnesium (Mg), calcium (Ca), ytterbium (Yb), chromium (Cr), nickel (Ni), gold oxide, platinum oxide, silver oxide, palladium oxide, iron oxide, graphene, carbon nanotubes (CNT), silver nanowires (Ag nanowires (Ag NW), indium tin oxide and poly(3,4-ethylenedioxythiophene) polystyrene sulfonate (PEDOT:PSS).

In addition, the first drain electrode 500a and the second drain electrode 500b each independently may comprise at least one selected from the group consisting of gold (Au), silver (Ag), platinum (Pt), titanium (Ti), aluminum (Al), tungsten (W), magnesium (Mg), calcium (Ca), ytterbium (Yb), chromium (Cr), nickel (Ni), gold oxide, platinum oxide, silver oxide, palladium oxide, iron oxide, graphene, carbon nanotubes (CNT), silver nanowires (Ag NW), indium tin oxide and poly(3,4-ethylenedioxythiophene) polystyrene sulfonate (PEDOT:PSS).

In addition, the substrate 600 may comprise at least one selected from the group consisting of glass, silicon, p-silicon, n-silicon, fluorine-doped tin oxide (FTO), indium tin oxide (ITO), indium zinc oxide (IZO), indium zinc tin oxide (IZTO), aluminum zinc oxide (AZO), indium tin oxide-silver-indium tin oxide (ITO-Ag-ITO), indium zinc oxide-silver-indium zinc oxide (IZO-Ag-IZO), indium zinc tin oxide-silver-indium zinc oxide (IZTO-Ag-IZTO), aluminum zinc oxide-silver-aluminum zinc oxide (AZO-Ag-AZO), nickel, stainless steel, zinc-coated carbon steel, pure carbon steel, copper, titanium, zinc, steel, polyester, polyethylene terephthalate (PET), polybutylene terephthalate (PBT), polyethylene naphthalate (PEN), polystyrene (PS), polymethyl methacrylate (PMMA), polyimide (PI), polyamide, polyethylene, polypropylene, polyurea, polyurethane poly(p-xylylene), parylene, polydimethylsiloxane (PDMS), Cytop and polyvinyl pyrrolidone (PVP).

In addition, referring to FIGS. 1 and 2, the non-volatile memory cell 1 may further comprise: a write word line (WWL) connected to a first gate electrode 100a of the write n-type transistor 10a; a write bit line (WBL) connected to a first source electrode 400a of the write n-type transistor 10a; a read bit line (RBL) connected to a second source electrode 400b of the read p-type transistor 10b; and a read word line (RWL) connected to a second drain electrode 500b of the read p-type transistor 10b; wherein the first drain electrode 500a of the write n-type transistor 10a may be connected to the second gate electrode 100b of the read p-type transistor 10b.

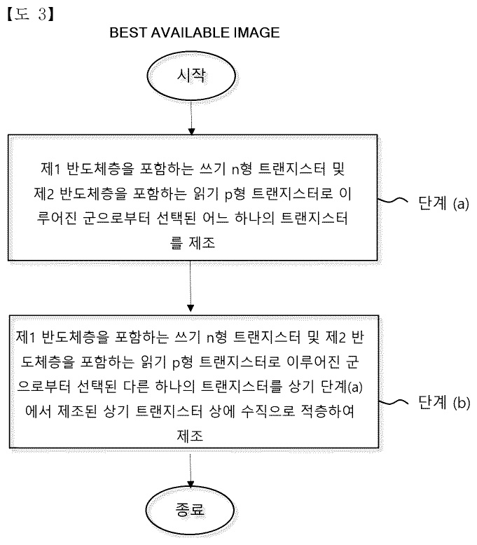

FIG. 3 is a flowchart showing a method for manufacturing a non-volatile memory cell according to an embodiment of the present disclosure. Referring to FIG. 2 and according to another aspect of the present disclosure provides a method for manufacturing a non-volatile memory cell 1, the method comprising: (a) manufacturing one transistor selected from the group consisting of a write n-type transistor 10a comprising a first semiconductor layer 300a and a read p-type transistor 10b comprising a second semiconductor layer 300b; and (b) stacking vertically the other transistor selected from the group consisting of the write n-type transistor 10a comprising the first semiconductor layer 300a and the read p-type transistor 10b comprising the second semiconductor layer 300b on the one transistor manufactured in step (a); wherein the first semiconductor layer 300a comprises an n-type semiconductor and the second semiconductor layer 300b comprises an amorphous p-type semiconductor.

In addition, the method for manufacturing a non-volatile memory cell 1 may further comprise, between step (a) and step (b), (a′) forming an insulating intermediate layer 700 on the transistor manufactured in step (a).

In addition, the temperature of the substrate of the non-volatile memory cell may be in a range of 5 to 50° C. in step (a) and step (b).

In addition, the first semiconductor layer 300a may be annealed at a temperature in a range of 150 to 400° C. in step (a) or step (b).

In addition, the second semiconductor layer 300b may be annealed at a temperature in a range of 150 to 400° C. in step (a) or step (b).

When using Si-based p-MOSFETs to utilize write n-type transistors and read p-type transistors with opposite polarities, the silicon-based process temperature is as high as 800° C. or higher and copper wiring melts at 450° C., which limits the implementation of vertical stacking. However, the present disclosure is not silicon-based but p-type tellurium oxide semiconductor-based. Therefore, the manufacturing method of the present disclosure can vertically stack 2T0C memory cells repeatedly at a low process temperature at which copper wiring does not melt, thereby significantly improving the memory integration density.

### EXAMPLES

Hereinafter, the examples of the present disclosure will be described. However, the examples are for illustrative purposes, and the scope of the present disclosure is not limited by the examples.

### Example 1: Fabrication of p-Type Thin Film Transistor Based on Tellurium Oxide (TeOₓ) Alloyed with Se

In order to deposit selenium alloyed tellurium oxide (TeOₓ) based semiconductor (Se alloyed TeOₓ) films, commercially available TeO₂ powder (with a purity of 97% or more) was used as an evaporation source. Meanwhile, Se among a small amount of chalcogen powder (S or Se) was mixed with TeO₂ at 10 to 20 mol % Se among 0.1-90 mol % (chalcogen/(chalcogen+TeO₂) mol %). The TeOx-based film was deposited using a conventional thermal evaporator. The Si⁺⁺/SiO₂ substrate temperature was room temperature (25° C.), and the vacuum pressure before evaporation was 10⁻³ Torr or less. The distance between the substrate and the boat loaded with TeO₂ was 2˜50 cm. The deposition rate was 0.1-1 Å s⁻¹. The thickness of the TeOₓ film (1˜100 nm) was monitored during the deposition. The deposited sample was first annealed at a temperature of 200° C. for 30 min in a N₂-filled glove box, and then further annealed at a temperature of 250° C. for 30 min in air. After that, the source and drain electrodes were each deposited using Ni to fabricate a thin film transistor (TFT).

### Example 2: Fabrication of n-Type Thin Film Transistor Based on n-MoS₂

### Fabrication Method of n-MoS₂-Based n-MOS Transistor

A Si⁺⁺ substrate with an over-doped silicon layer and an insulating layer thereon was used, and the substrate temperature was room temperature (25° C.). Here, the over-doped silicon layer was used as a rear electrode. Then, an Al₂O₃ dielectric layer was deposited with a thickness of 60 nm as a gate insulating film by atomic layer deposition (ALD). On top of that, the deposition of the two-dimensional semiconductor layer MoS₂ was formed by spin coating at a speed of 2,000 rpm for 20 seconds using a solution containing MoS₂ flakes. And the deposited substrate was annealed at 200° C. for 1 hour in a glove box under nitrogen conditions. After that, the source electrode and the drain electrode were each deposited by thermal deposition in a high vacuum using nickel to fabricate an n-MoS₂-based n-type thin film transistor.

### Comparative Example 1: Fabrication of p-Channel Thin Film Transistor Based on a Tellurium Oxide (TeOₓ)

A thin film transistor (TFT) was fabricated in the same manner as in Example 1, except that a tellurium oxide without selenium (Se) alloy was prepared instead of preparing a tellurium oxide alloyed with selenium (Se). However, the p-type transistor was fabricated on the n-type transistor.

### Example 3: Fabrication of a Capless Non-Volatile Memory Cell with a Vertical Stacking Structure (Vertical 2T0C DRAM CMOS)

FIG. 1 is a cross-sectional view of a non-volatile memory cell in which a read p-type transistor 10b is vertically stacked on a write n-type transistor 10a according to an embodiment of the present disclosure, FIG. 2 is a circuit diagram of a non-volatile memory cell in which a write n-type transistor and a read p-type transistor are combined according to an embodiment of the present disclosure and FIG. 3 is a flowchart showing a method for manufacturing a non-volatile memory cell according to an embodiment of the present disclosure. Referring to FIGS. 1 to 3, first, a Ni gate electrode 100a was deposited on a silicon substrate 600 to a thickness of 15 nm by a thermal deposition method and patterned by photolithography. Then, an Al₂O₃ dielectric layer 200a was deposited to a thickness of 60 nm by atomic layer deposition (ALD). After that, the n-type semiconductor layer 300a was deposited by a spin coating process using a solution containing MoS₂ flakes, and annealed at 200° C. A shadow mask was used to form the Ni source 400a/drain 500a electrodes, thereby completing the first n-MOS transistor, the write n-type transistor 10a.

In order to form an insulating intermediate layer between an n-MOS transistor and a p-MOS transistor, an Al₂O₃ thin film (60 nm) was formed as a first insulating intermediate layer 710 on the n-MOS transistor using a conventional photolithography method and on top of that, a SU8 photoresist was formed in a desired pattern as a second insulating intermediate layer 720, so the insulating intermediate layer 700 was laminated.

A via hole was formed in the insulating intermediate layer 700 up to the drain electrode 500a of the n-MOS transistor 10a, and nickel was deposited on the via hole and the insulating intermediate layer 700 to form a gate electrode 100b. The gate electrode 100b of the p-MOS transistor 10b and the drain electrode 500a of the n-MOS transistor 10a were electrically connected by forming a conductive via 800. The via hole was formed using Ar plasma with a mask placed thereon by the RIE method. Al₂O₃ was deposited as a dielectric layer 200b on the gate electrode 100b by atomic layer deposition (ALD). To deposit semiconductor layer 300b based on tellurium oxide (TeOₓ) alloyed with Se (Se alloyed Te/Oₓ), commercially available TeO₂ powder (purity of 97% or more) was used as an evaporation source. Meanwhile, Se among a small amount of chalcogen powder (S or Se) was mixed with TeO₂ at 10 to 20 mol % Se among 0.1-90 mol % (chalcogen/(chalcogen+TeO₂) mol %), and the TeOₓ-based film was deposited using a conventional thermal evaporator. The substrate temperature was room temperature (25° C.), and the vacuum pressure before evaporation was 10⁻³ Torr or less. The distance between the substrate and the TeO₂-loaded boat was 2 to 50 cm. The deposition rate was 0.1 to 1 Å s⁻¹. The thickness of the TeOₓ film (1 to 100 nm) was monitored during the deposition. The deposited sample was first annealed at a temperature of 200° C. for 30 minutes in a N₂-filled glove box, and then further annealed in air at a temperature of 250° C. for 30 minutes. Thereafter, the source 400b and drain electrodes 500b were each deposited using Ni to stack a read p-type transistor 10b, which is a p-MOS transistor 10b. Here, a write word line (WWL) is connected to the gate electrode 100a of the write n-type transistor 10a, a write bit line (WBL) is connected to the source electrode 400a of the write n-type transistor 10a, a read bit line (RBL) is connected to the source electrode 400b of the read p-type transistor 10b, and a read word line (RWL) is connected to the drain electrode 500b of the read p-type transistor 10b, so that a capless non-volatile memory cell having a vertical stacked structure (CMOS of vertical 2T0C DRAM) is manufactured.

### Test Examples

### Test Example 1: XPS Se 3p Spectrum

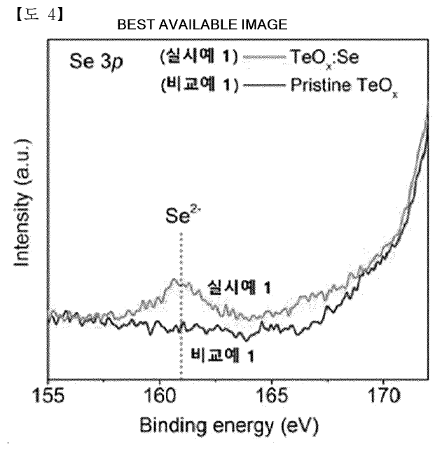

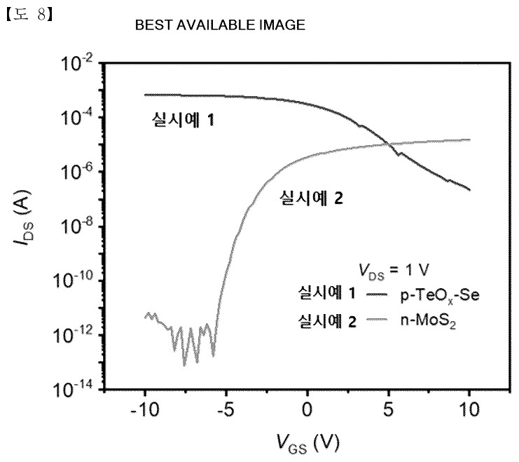

FIG. 4 is a graph showing the XPS (X-ray photoelectron spectroscopy) selenium (Se) 3p spectrum of TeOₓ:Se alloyed with selenium (Se) according to Example 1 and a pristine TeOₓ sample not alloyed with selenium (Se) according to Comparative Example 1. Referring to FIG. 8, it can be confirmed that the selenium (Se) of the alloy exists as an anion phase of Se²⁻ in the TeOₓ thin film.

### Test Example 2: Electrical Characteristics of Amorphous p-Channel TeOₓ:Se TFTs

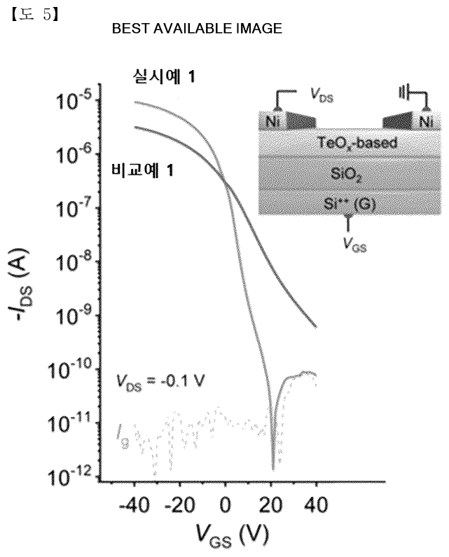

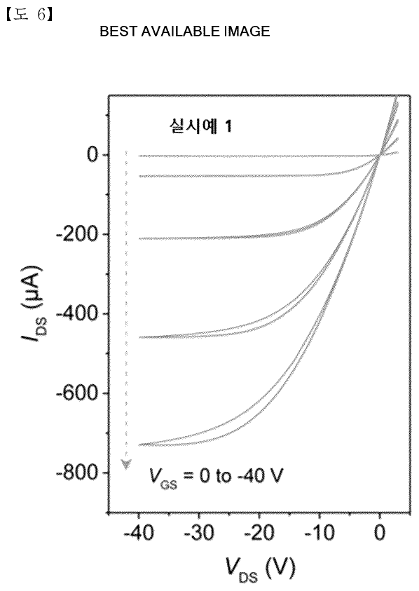

FIG. 5 is a graph showing the transfer characteristics of TeOₓ:Se and TeOₓ thin film transistors (TFTs) according to Example 1 and Comparative Example 1 of the present disclosure, and FIG. 6 is a graph showing the output curve of the TeOₓ:Se thin film transistor (TFT) according to Example 1.

### Test Example 3: TFT Field Effect Hole Mobility (μₙ)

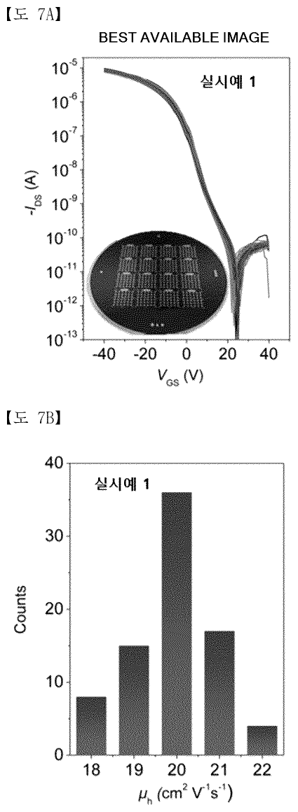

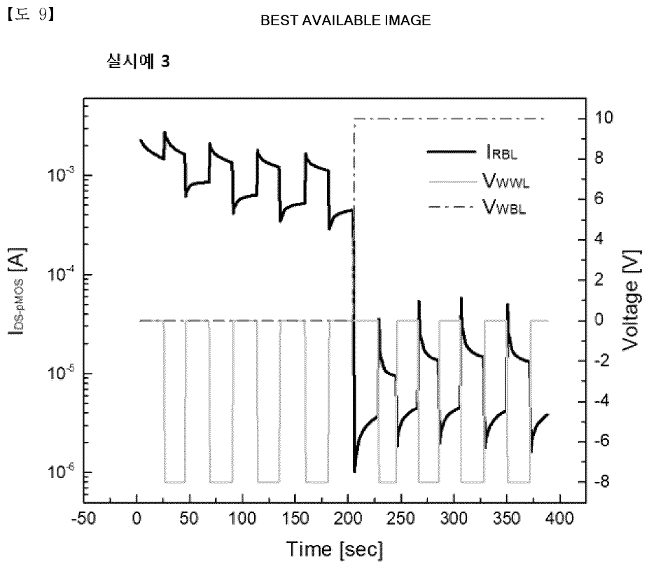

FIG. 7A is a graph showing the transfer curves of 80 TeOₓ:Se thin film transistor (TFT) devices manufactured on a 4-inch wafer under optimized conditions (VDS=−0.1 V) according to Example 1, and the inserted figure is an optical image of the TFT array on a 4-inch SiO₂ wafer and FIG. 7B is a graph showing statistical results of field-effect hole mobility (μₙ) of the thin film transistor (TFT) according to Example 1 of the present disclosure. Referring to FIGS. 9A and 9B, it can be seen that the average mobility is 20 cm²/VS and the on/off ratio of the drain current is 10⁷.

### Test Example 4: Characteristic Analysis of n-Type Transistor and p-Type Transistor

FIG. 8 is a transfer curve of Examples 1 and 2 of the present disclosure. Referring to FIG. 8, it can be seen that the p-type transistor of Example 1 and the n-type transistor of Example 2 are operating normally, respectively.

### Test Example 5: Characteristic Analysis of Vertical Stacked Structure Capless Non-Volatile Memory Cell (2T0C DRAM CMOS)

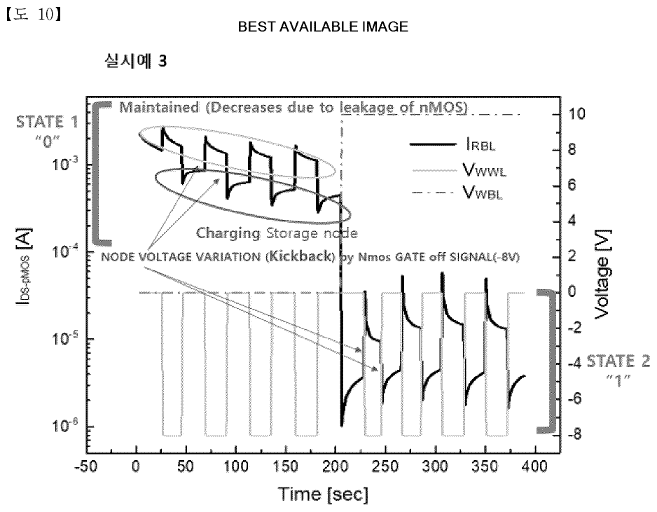

FIG. 2 is a circuit diagram of a non-volatile memory cell according to Example 3 of the present disclosure in which a write n-type transistor and a read p-type transistor are stacked vertically and combined, and FIGS. 9 and 10 are characteristic analysis graphs of the vertically stacked structure capless non-volatile memory cell (CMOS of 2T0C DRAM) according to Example 3 of the present disclosure. Referring to FIGS. 2, 9, and 10, it can be seen that the current of the pMOS changes because the current from the drain electrode of the write-type transistor fills the storage node, thereby changing the gate voltage of the read-type transistor. In addition, the memory operation could be confirmed because the pMOS current changed significantly depending on the V_{WBL} voltage change.

The scope of the present disclosure is defined by the following claims rather than the above detailed description, and all changes or modifications derived from the meaning and scope of the claims and their equivalent concepts should be interpreted as falling into the scope of the present disclosure.

1. A non-volatile memory cell comprising a write n-type transistor comprising a first semiconductor layer and a read p-type transistor comprising a second semiconductor layer,
wherein the first semiconductor layer comprises an n-type semiconductor, and
the second semiconductor layer comprises an amorphous p-type semiconductor.

2. The non-volatile memory cell of claim 1, wherein the non-volatile memory cell is a capless non-volatile memory cell that does not comprise a capacitor.

3. The non-volatile memory cell of claim 1, wherein the amorphous p-type semiconductor comprises:
a chalcogen atom comprising at least one selected from the group consisting of a selenium atom (Se) and a sulfur atom (S); and
a tellurium composite comprising a tellurium (Te) atom and a tellurium oxide.

4. The non-volatile memory cell of claim 3, wherein the chalcogen atom is alloyed with the tellurium composite.

5. The non-volatile memory cell of claim 3, the amorphous p-type semiconductor is represented by Chemical Formula 1 below.
TeOₓ:M [Chemical Formula 1]
in Chemical Formula 1, M is a sulfur atom (S) or a selenium atom (Se), and x is in a range of 0<x<2.

6. The non-volatile memory cell of claim 3, wherein the tellurium atom of the amorphous p-type semiconductor comprises an ionization state of Te⁴⁺, an ionization state of Te²⁺ and a non-ionization state of Te⁰.

7. The non-volatile memory cell of claim 3, wherein the tellurium oxide comprises a tellurium monoxide (TeO) and a tellurium dioxide (TeO₂).

8. The non-volatile memory cell of claim 3, wherein the amorphous p-type semiconductor is in an oxygen-deficient state.

9. The non-volatile memory cell of claim 1, wherein the write n-type transistor and the read p-type transistor are alternately vertically stacked.

10. The non-volatile memory cell of claim 9, wherein the write n-type transistor and the read p-type transistor are vertically stacked and repeatedly stacked multiple times in the vertical direction.

11. The non-volatile memory cell of claim 9, wherein the write n-type transistor comprises a first gate electrode, a first insulating layer positioned on the first gate electrode, a first semiconductor layer positioned on the first insulating layer, a first source electrode and a first drain electrode, and
the read p-type transistor comprises a second gate electrode, a second insulating layer positioned on the second gate electrode, a second semiconductor layer positioned on the second insulating layer, a second source electrode and a second drain electrode, and
an insulating intermediate layer is positioned between the write n-type transistor and the read p-type transistor.

12. The non-volatile memory cell of claim 11, wherein the insulating intermediate layer comprises a first insulating intermediate layer comprising at least one selected from the group consisting of SU-8, CYTOP, benzocyclobutene (BCB) and polyimide; and
a second insulating intermediate layer positioned on the first insulating intermediate layer and comprising at least one selected from the group consisting of Al₂O₃, HfO₂, a laminate of Al₂O₃ and HfO₂ (Al₂O₃/HfO₂), CYTOP, BCB and polyimide.

13. The non-volatile memory cell of claim 11, further comprising a via electrically connecting the first drain electrode of the write n-type transistor and the second gate electrode of the read p-type transistor.

14. The non-volatile memory cell of claim 1, wherein the n-type semiconductor comprises at least one selected from the group consisting of MoS₂, ZnO, In₂O₃, TiO₂, Ga₂O₃, VO₂, V₄O₉, VOₓ, indium tin oxide (ITO), indium zinc oxide (IZO), indium zinc tin oxide (IZTO), indium gallium zinc oxide (IGZO), indium tungsten oxide (IWO) and zinc tin oxide (ZTO).

15. The non-volatile memory cell of claim 1, further comprising:
a write word line (WWL) connected to a first gate electrode of the write n-type transistor;
a write bit line (WBL) connected to a first source electrode of the write n-type transistor;
a read bit line (RBL) connected to a second source electrode of the read p-type transistor; and
a read word line (RWL) connected to a second drain electrode of the read p-type transistor;
wherein the first drain electrode of the write n-type transistor is connected to the second gate electrode of the read p-type transistor.

16. A method for manufacturing a non-volatile memory cell, the method comprising:
(a) manufacturing one selected from the group consisting of a write n-type transistor comprising a first semiconductor layer and a read p-type transistor comprising a second semiconductor layer; and
(b) stacking vertically the other selected from the group consisting of the write n-type transistor comprising the first semiconductor layer and the read p-type transistor comprising the second semiconductor layer on the transistor manufactured in step (a);
wherein the first semiconductor layer comprises an n-type semiconductor and the second semiconductor layer comprises an amorphous p-type semiconductor.

17. The method of claim 16, further comprising, between step (a) and step (b),
(a′) forming an insulating intermediate layer on the transistor manufactured in step (a).

18. The method of claim 16, wherein the temperature of the substrate of the non-volatile memory cell is in a range of 5 to 50° C. in step (a) and step (b).

19. The method of claim 16, wherein the first semiconductor layer is annealed at a temperature in a range of 150 to 400° C. in step (a) or step (b).

20. The method of claim 16, wherein the second semiconductor layer is annealed at a temperature in a range of 150 to 400° C. in step (a) or step (b).
